(19) United States
(12) Patent Application Publication
(10) Pub. No.: US 2007/0075376 A1
(43) Pub. Date: Apr. 5, 2007

(54) Semiconductor device

(76) Inventor: Yoshinobu Kono, Niiza-shi (JP)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/543,618

(22) Filed: Oct. 5, 2006

(30) Foreign Application Priority Data
Oct. 5, 2005 (JP) 2005-293017
Sep. 13, 2006 (JP) 2006-247581

(51) Int. Cl. H01L 29/76

(52) U.S. Cl. 257/370

(57) ABSTRACT

A semiconductor device comprises a semiconductor substrate having an N-type base region, a collector region, a P-type base region, an emitter region, a collector-shorting region, a buffer region, and a P-type semiconductor region, and a gate bus line disposed on the P-type semiconductor region through an insulating film. The collector-shorting region is formed at a region in the collector region opposite to the gate bus line. Accordingly, it is possible to secure the area of the collector region which is opposite to a gate electrode. The collector-shorting region discharges carriers well.

### BACKGROUND OF THE INVENTION

1. Field of the Invention

The present invention relates to a semiconductor device, and more particularly, an insulated gate type semiconductor device.

2. Description of the Related Art

An insulated gate bipolar transistor (hereinafter, “IGBT” ) has a high input impedance that a field effect transistor has and a high current drive capability that a bipolar transistor has, and is particularly suitable for use as a power switching device.

Conventional semiconductor devices have a semiconductor substrate, a collector electrode, a gate electrode, and an emitter electrode. The semiconductor substrate has an N-type base region, a P-type base region formed in the surface region of the N-type base region, an emitter region formed in the surface region of the P-type base region, a buffer region formed on the entire bottom surface of the N-type base region, and a collector region formed on the entire bottom surface of the buffer region. The collector electrode is connected to the bottom surface of the collector region. The gate electrode is connected to the upper surface of the semiconductor substrate through a gate insulating film. The emitter electrode is connected to the upper surface of the semiconductor substrate. An interlayer insulating film is formed between the gate electrode and the emitter electrode.

In such semiconductor devices, as the buffer region is formed on the entire upper surface of the collector region, carriers are charged in the buffer region or the N-type base region in the vicinity of the buffer region when the semiconductor device is turned off. Because there is no path for discharging the charged carriers, a tail current continues to flow until the carriers recombine and disappear. This results in a delay in an off speed (switching speed).

The off speed can be made faster by a method of introducing a lifetime killer which prompts recombination of the carriers. The method however raises a problem such that a forward voltage increases.

Thus, there has been proposed a semiconductor device where a collector-shorting region, which discharges the carriers, is formed in the collector region to rapidly discharge the carriers in the buffer region or the N-type base region in the vicinity thereof.

Unexamined Japanese Patent Application KOKAI publication No. H5-3205 discloses a semiconductor device which can discharge carriers charged in a buffer region or an N-type base region in the vicinity thereof through a collector-shorting region when the semiconductor device is turned off. This makes it possible to make an off speed faster. As the lifetime killer is not diffused, the forward voltage is not increased.

To make the off speed (switching speed) faster in the semiconductor device disclosed in the publication No. H5-3205, it is necessary to form the collector-shorting region widely to some extent. However, increasing the area of the collector-shorting region reduces the area of the collector region, so that the quantity of holes to be supplied from a collector region in operation is reduced. Thus, the degree of conductivity modulation becomes smaller, an MOS operation becomes prominent, and the forward voltage property which is the advantage of an IGBT is degraded.

Therefore, a semiconductor device that has a good switching speed and a good forward voltage property, i.e., a semiconductor device that can maintain a relatively low forward voltage, is desired.

### SUMMARY OF THE INVENTION

The present invention has been made in view of the foregoing circumstance, and it is an object of the invention to provide a semiconductor device that has a good forward voltage property and a switching speed.

To achieve the object, a semiconductor device according to the first aspect of the invention is a semiconductor device which comprises:

a semiconductor substrate having a first semiconductor region of a first conductive type, a second semiconductor region of a second conductive type formed in a surface region of one principal surface of the first semiconductor region, a third semiconductor region of the first conductive type formed at a surface region of the second semiconductor region, and a fourth semiconductor region of the second conductive type formed on an other principal surface of the first semiconductor region;

a gate electrode disposed on the second semiconductor region through an insulating film;

a gate bus line electrically connected to the gate electrode; and

a fifth semiconductor region of the first conductive type formed in a region in the fourth semiconductor region opposite to the gate bus line.

The gate bus line has, for example, an annular portion circularly formed on a periphery portion of the semiconductor substrate. In this case, the gate electrode is disposed inward the annular portion of the gate bus line.

It is preferable that the gate bus line should further have a stem portion electrically connected to the annular portion and disposed in such a manner as to extend toward a center of the annular portion. In this case, the gate electrode is electrically connected to the stem portion.

It is preferable that the fifth semiconductor region should be formed in such a manner as to protrude from the fourth semiconductor region.

It is preferable that the gate bus line should be formed on the one principal surface of the first semiconductor region through an insulating layer, and a sixth semiconductor region of the second conductive type should be formed at a surface region of the first semiconductor region opposite to the gate bus line.

It is preferable that a width between the sixth semiconductor region and the second semiconductor region spaced away from each other is almost the same as a width between adjoining portions of the second semiconductor region spaced away from each other.

The semiconductor device may further comprise a seventh semiconductor region of the first conductive type formed at a region in the fourth semiconductor region opposite to the gate electrode.

It is preferable that the fifth semiconductor region should be formed in such a manner as to protrude from the fourth semiconductor region, and the seventh semiconductor region should be so formed as to have the almost same thickness as a thickness of the fourth semiconductor region.

It is preferable that the fifth semiconductor region should be formed in such a manner as to have an area greater than or equal to three times an area of the seventh semiconductor region. It is further preferable that the fifth semiconductor region should be formed in such a manner as to have an area greater than or equal to five times an area of the seventh semiconductor region.

The semiconductor device may further comprise a gate electrode pad (25) formed on the semiconductor substrate, and electrically connected to the gate bus line. In this case, the fifth semiconductor region is formed in regions in the fourth semiconductor region opposite to the gate bus line and the gate electrode pad.

The semiconductor device may further comprise an eighth semiconductor region of the first conductive type formed between the first semiconductor region and the fourth semiconductor region.

### BRIEF DESCRIPTION OF THE DRAWINGS

These objects and other objects and advantages of the present invention will become more apparent upon reading of the following detailed description and the accompanying drawings in which:

FIG. 1 is a top plan view illustrating a structural example of a semiconductor device according to a first embodiment of the invention;

FIG. 2 is a cross-sectional view of the semiconductor device illustrated in FIG. 1 along a line A-A;

FIG. 3 is a cross-sectional view of the semiconductor device illustrated in FIG. 1 along a line B-B;

FIG. 4 is a top plan view illustrating a structural example of a semiconductor device according to a second embodiment of the invention;

FIG. 5 is a cross-sectional view of the semiconductor device illustrated in FIG. 4 along a line C-C; and

FIG. 6 is a top plan view illustrating a modified example of the invention.

### DETAILED DESCRIPTION OF THE PREFERRED EMBODIMENTS

Semiconductor devices according to respective embodiments of the invention will be explained with reference to the accompanying drawings.

In all embodiments, explanations will be given of cases where insulated gate bipolar transistors (IGBT) are taken as examples of semiconductor devices.

### First Embodiment

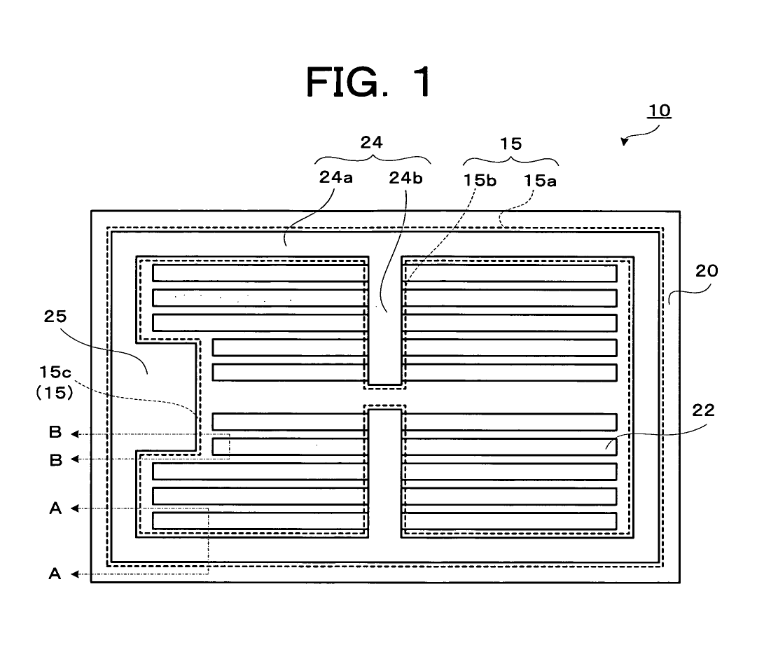

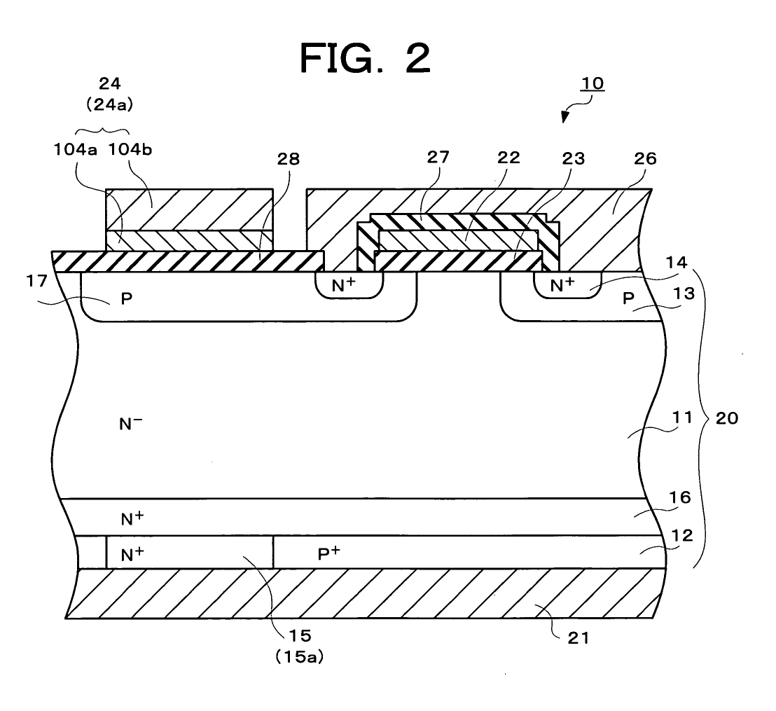

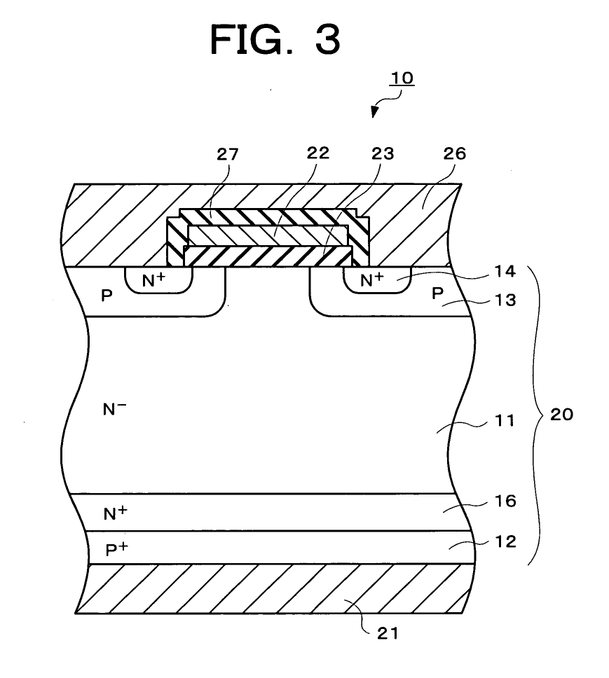

FIG. 1 is a top plan view illustrating a semiconductor device 10 of the first embodiment of the invention. FIG. 2 is a cross-sectional view of the semiconductor device 10 illustrated in FIG. 1 along a line A-A. FIG. 3 is a cross-sectional view illustrating the semiconductor device 10 illustrated in FIG. 1 along a line B-B. Note that in FIG. 1, a gate bus line 24, a gate electrode pad 25, and a collector-shorting region 15 are particularly illustrated, and an emitter electrode 26 and the like are omitted for the sake of descriptive convenience.

As illustrated in FIGS. 1 and 2, the semiconductor device 10 has a semiconductor substrate 20, a collector electrode 21, a gate electrode 22, a gate insulating film 23, the gate bus line 24, the gate electrode pad 25, the emitter electrode 26, an interlayer insulating film 27, and an insulating film 28.

The semiconductor substrate 20 has an N-type base region 11, a collector region 12, a P-type base region 13, an emitter region 14, a collector-shorting region 15, a buffer region 16, and a P-type semiconductor region 17.

The N-type base region 11 comprises an N-type semiconductor region in which N-type impurities like phosphorus are diffused. The N-type base region 11 is formed to a thickness of, for example 50μm or so with an impurity concentration of, for example 2×10¹⁴ cm³ or so.

The collector region 12 comprises a P-type semiconductor region in which P-type impurities like boron are diffused. The collector region 12 is formed on the other principal surface, e.g., bottom surface of the N-type base region 11. A collector electrode 21 is formed under the collector region 12. In the embodiment, the collector region 12 is formed on the bottom surface of the N-type base region 11 through the buffer region 16. Thus, the collector region 12 is formed on the bottom surface of the buffer region 16. The collector region 12 injects holes in the N-type base region 11 when the semiconductor device 10 is in operation, and brings about conductivity modulation.

The collector region 12 is formed to a thickness of, for example, 5μm or so. The P-type impurity concentration of the collector region 12 is, for example, 2×10¹⁸ cm⁻or so, higher than the impurity concentration of the P-type base region 13. In accordance with the level of requisition of conductivity modulation, the P-type impurity concentration of the collector region 12 may be lower than that of the P-type base region 13.

The P-type base region 13 comprises a P-type semiconductor region in which P-type impurities like boron are diffused. The P-type base region 13 is formed in a predetermined surface region of the N-type base region 11. The P-type base region 13 is formed in such a manner as to have a thickness of, for example, 4μm or so. The P-type impurity concentration of the P-type base region 13 is, for example, 1×10¹⁸ cm⁻or so, lower than the impurity concentration of the collector region 12.

The emitter region 14 comprises an N-type semiconductor region in which N-type impurities like phosphorus are diffused. The emitter region 14 is formed at a predetermined surface region of the P-type base region 13. The emitter electrode 26 is formed on the upper surface of the emitter region 14. The emitter region 14 is to a thickness of, for example, 0.6 μm or so. The N-type impurity concentration of the emitter region 14 is, for example, 1×10¹⁹, higher than that of the N-type base region 11.

The gate electrode 22 is disposed on the P-type base region 13 (channel formation region) between the N-type base region 11 and the emitter region 14 through the gate insulating film 23. As a voltage is applied to the gate electrode 22, a channel is formed in the P-type base region 13. In the embodiment, as will be discussed later, a plural of the gate electrodes 22 are formed in an approximately rectangular band-like shape, and are arranged side by side. Because the P-type base region 13 and the emitter region 14 are formed below both ends of the gate electrode 22, they are formed in approximately rectangular band-like shapes, and are arranged side by side.

In the embodiment, as illustrated in FIG. 2, the emitter region 14 is formed in the P-type semiconductor region 17 formed under the gate bus line 24.

Unlike the emitter regions 14 formed in the P-type base region 13, the emitter region 14 formed in the P-type semiconductor region 17 is so formed as to be away from the gate bus line 24. Accordingly, when voltage is applied to the gate electrode 22 through the gate bus line 24, no channel is formed in the emitter region 14 formed in the P-type semiconductor region 17.

The collector-shorting region 15 comprises an N-type semiconductor region in which N-type impurities like phosphorus are diffused. As illustrated in FIG. 2, the collector-shorting region 15 is formed under the buffer region 16. That is, the collector-shorting region 15 is formed in the collector region 12 in such a manner as to penetrate the collector region 12. The collector-shorting region 15 comprises, as illustrated in FIG. 1, an annular portion 15a and a stem portion 15b which are formed in such a manner as to respectively oppose an annular portion 24a and a stem portion 24b of the gate bus line 24 to be discussed later, and a rectangular portion 15c formed in such a manner as to face the gate electrode pad 25. Apparently, the collector-shorting region 15 is formed only in that portion of the collector region 12 which oppose the gate bus line 24 and the gate electrode pad 25. Accordingly, unlike the conventional semiconductor devices, the semiconductor device of the embodiment does not reduce the area of the collector region 12 which faces the gate electrode 22.

The collector-shorting region 15 is formed in such a manner as to have approximately the same thickness as that of the collector region 12, or formed thicker than the collector region 12. The collector-shorting region 15 is so formed as to have a higher impurity concentration than that of the N-type base region 11. Specifically, the collector-shorting region 15 is formed to a thickness of, for example, 4 to 6μ m or so. The N-type impurity concentration of the collector-shorting region 15 is, for example, 1×10¹⁹ or so. × 10¹⁹ cm⁻³ or so.

The collector electrode 21 is formed under the collector region 12 and the collector-shorting region 15. The collector-shorting region 15 functions to discharge carriers charged in the buffer region 16 or the N-type base region 11 in the vicinity thereof to the collector electrode 21 when the semiconductor device 10 is turned off, and makes the off speed of the semiconductor device 10 faster. Accordingly, unlike in the conventional semiconductor devices having no collector-shorting region, the carriers are discharged from the collector-shorting region 15 when the semiconductor device 10 is turned off. Therefore, the semiconductor device 10 has a good off speed.

Because it is not necessary to reduce the area of the collector region 12 opposite to the gate electrode 22, holes are well supplied from the collector region 12 when the semiconductor device 10 is in operation. As a result, the semiconductor device 10 has a good forward voltage property.

The buffer region 16 comprises an N-type semiconductor region in which N-type impurities like phosphorus are diffused. The buffer region 16 is formed between the bottom surface of the N-type base region 11 and the upper surfaces of the collector region 12 and the collector-shorting region 15.

The P-type semiconductor region 17 comprises a P-type semiconductor region in which P-type impurities like boron are diffused. As illustrated in FIG. 2, the P-type semiconductor region 17 is formed in the surface region of the N-type base region 11 which corresponds to that area where the gate bus line 24 is formed. It is not illustrated in FIGS. 1 and 2, the P-type semiconductor region 17 is also formed in the surface region of the N-type base region 11 which corresponds to that area where the gate electrode 22 is formed. The P-type semiconductor region 17 and the P-type base region 13 are electrically separated from each other via the N-type base region 11. Note that the P-type semiconductor region 17 formed below the gate bus line 24 and the P-type semiconductor region 17 formed below the gate electrode pad 25 may be electrically separated from each other via the N-type base region 11.

As the P-type semiconductor region 17 is formed at a surface region of the N-type base region 11 which corresponds to that area where the gate bus line 24 is formed, a depletion layer expands well from a PN junction constituted by the P-type semiconductor region 17 and the N-type base region 11 when the semiconductor device 10 is turned off. This results in improvement of the withstand voltage of the semiconductor device 10.

It is preferable that a width between the P-type semiconductor region 17 and the P-type base region 13 spaced away from each other and a width between adjoining portions of the P-type base regions 13 spaced away from each other should be so set as to be almost the same. In this case, the semiconductor device 10 can have a higher voltage withstandability.

The P-type semiconductor region 17 may be formed simultaneously in a process of forming the P-type base region 13, or may be formed in a separate process. In a case where the P-type semiconductor region 17 is formed in the separate process, the thickness of the P-type semiconductor region 17 can be changed appropriately.

The collector electrode 21 is made of a conductive material like aluminum. The collector electrode 21 is formed on the bottom surfaces of the collector region 12 and the collector-shorting region 15 entirely.

The gate electrode 22 is made of a conductive material like polysilicon in which impurities are diffused to have an electrical conductivity. The gate electrode 22 is disposed on the P-type base region 13 (channel forming region) between the N-type base region 11 and the emitter region 14 via the gate insulating film 23.

As illustrated in FIG. 1, the gate electrode 22 is formed in an approximately rectangular band-like shape. The gate electrode 22 is provided in such a way that portions thereof extend from stem portions 24b of the gate bus line 24 to be discussed later toward the end portions thereof and are arranged side by side.

The gate electrode 22 and the gate bus line 24 are electrically connected. The gate bus line 24 is electrically connected to the gate electrode pad 25. Thus, operation voltage for operating the semiconductor device 10 is externally supplied to the gate electrode 22 through the gate electrode pad 25 and the gate bus line 24.

The gate insulating film 23 is made of an insulating material like a silicon oxide film. As illustrated in FIGS. 2 and 3, the gate insulating film 23 is formed on the upper surfaces of the N-type base region 11, the P-type base region 13, and the emitter region 14.

As illustrated in FIG. 1, the gate bus line 24 comprises an annular portion 24a and stem portions 24b. The annular portion 24a is formed on the periphery portion of the semiconductor substrate 20 in an approximately rectangular ring-like shape. The stem portions 24b are formed in such a manner as to extend from two opposite longer edges of the middle of the annular portion 24a toward the center thereof. As illustrated in FIG. 1, the gate electrode 22 or the like is formed at the region surrounded by the annular portion 24a and stem portions 24b of the gate bus line 24 in such a way that the band-like portions of the gate electrode 22 are arranged side by side, and this region operates as a single device. In the embodiment, the region surrounded by the gate bus line 24 is particularly called a cell region (device operation region).

As illustrated in FIG. 2, the gate bus line 24 comprises, for example, a polysilicon layer 104a which is formed by elongating the gate electrode 22, and an aluminum layer 104b stacked on the polysilicon layer 104a. The gate bus line 24 may be formed without elongating the gate electrode 22.

The gate electrode pad 25 is made of a conductive material like aluminum. As illustrated in FIG. 1, the gate electrode pad 25 is formed in an approximately rectangular shape. The gate electrode pad 25 is formed in contact with the annular portion 24a of the gate bus line 24. Accordingly, as voltage is externally applied to the gate electrode pad 25, operation voltage is applied to the gate electrode 22 from the gate electrode pad 25 through the gate bus line 24. Like the gate bus line 24, the gate electrode pad 25 has a double-layer structure of a polysilicon layer and an aluminum layer.

The emitter electrode 26 is made of a conductive material like aluminum. The emitter electrode 26 covers the emitter region 14 and the interlayer insulating film 27 formed on the gate electrode 22 and the gate insulating film 23.

The interlayer insulating film 27 is made of an insulating material like a silicon oxide film. As illustrated in FIGS. 2 and 3, the interlayer insulating film 27 is formed between the gate electrode 22 and the emitter electrode 26, and electrically isolates them.

The insulating layer 28 is made of an insulating material like a silicon oxide film. The insulating layer 28 is also formed between the gate bus line 24 and the P-type semiconductor region 17. Though not illustrated in the figure, the insulating layer 28 is formed under the gate electrode pad 25.

According to the semiconductor device 10 of the embodiment employing the foregoing structure, because the collector-shorting region 15 is formed in a region opposite to the gate bus line 24 and the gate electrode pad 25, the area of the collector region 12 in the cell region (device operation region) is not greatly reduced by the collector-shorting region 15. Thus, holes are supplied well from the collector region 12, so that the semiconductor device 10 can have a good forward voltage property without lowering the degree of conductivity modulation of the device.

When the semiconductor device 10 is turned off, carriers charged in the buffer region 16 or the N-type base region 11 in the vicinity of the buffer region 16 are rapidly discharged through the collector-shorting region 15 formed in the region opposite to the gate bus line 24 and the gate electrode pad 25. Accordingly, the semiconductor device 10 has a good off speed.

### Second Embodiment

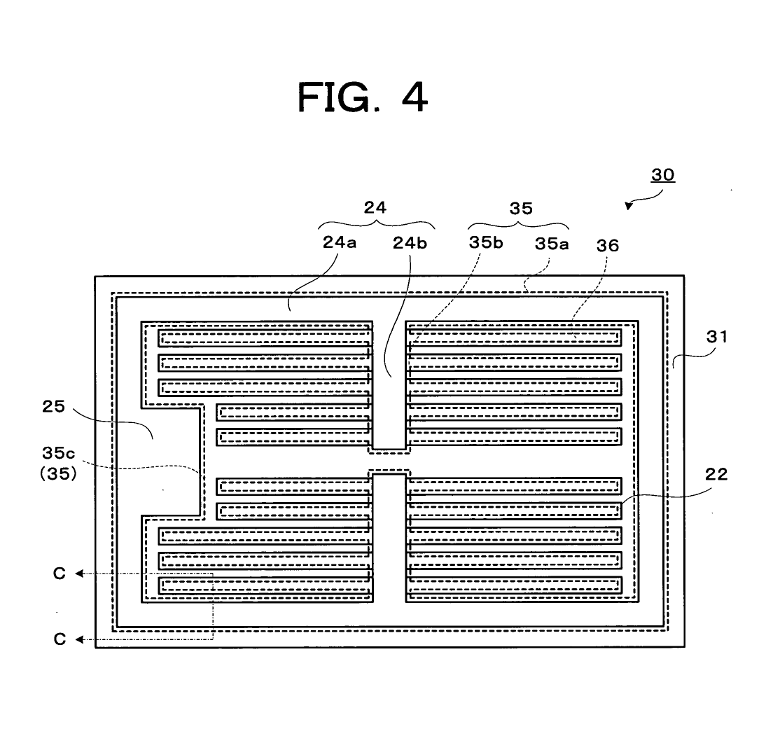

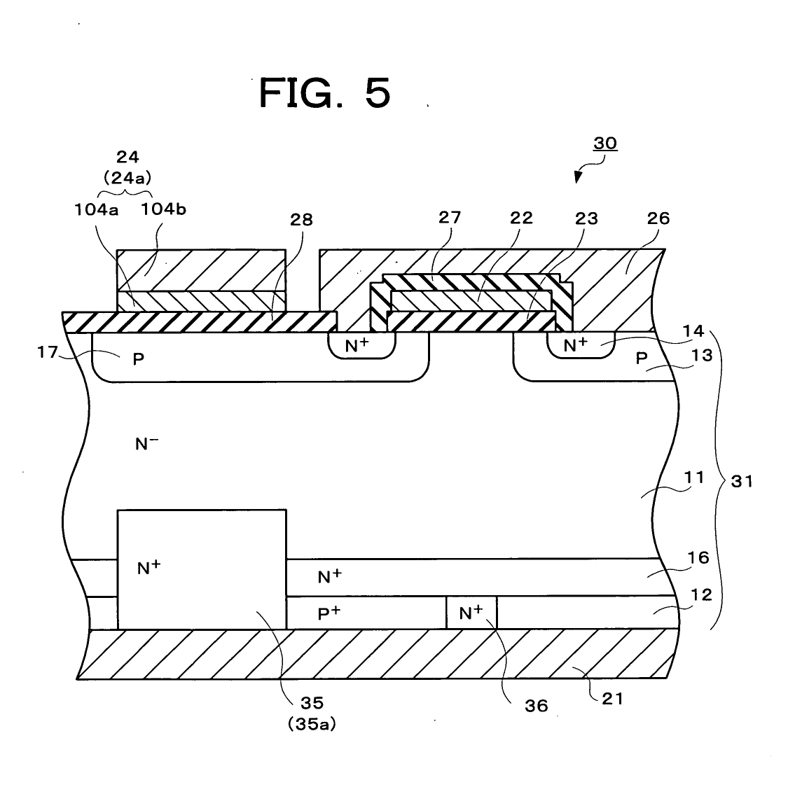

Next, a semiconductor device according to the second embodiment of the invention will be explained with reference to the accompanying drawings. FIG. 4 is a top plan view illustrating a semiconductor device 30 of the second embodiment. FIG. 5 is a cross-sectional view along a line C-C in FIG. 4. The difference of the semiconductor device 30 of the embodiment from the semiconductor device 10 of the first embodiment is that a collector-shorting region is formed in a region opposite to the gate electrode 22. That is, the semiconductor device 30 of the embodiment has collector regions formed at both of a region opposite to the gate electrode 22 and a region opposite to the gate bus line 24 and the gate electrode pad 25. The same structural portions as those of the first embodiment will be denoted by the same reference numbers, and the detailed explanations thereof will be omitted.

As illustrated in FIGS. 4 and 5, the semiconductor device 30 has a semiconductor substrate 31, the collector electrode 21, the gate electrode 22, the gate insulating film 23, the gate bus line 24, the gate electrode pad 25, the emitter electrode 26, and the interlayer insulating film 27. The semiconductor substrate 31 has the N-type base region 11, the collector region 12, the P-type base region 13, the emitter region 14, the buffer region 16, a first collector-shorting region 35, and a second collector-shorting region 36.

The first collector-shorting region 35 comprises an N-type semiconductor region in which N-type impurities like phosphorus are diffused. The impurity concentration of the first collector-shorting region 35 is higher than that of the N-type base region 11. The impurity concentration of the first collector-shorting region 35 is, for example, 1×10^{19 cm}⁻or so.

As illustrated in FIG. 4, the first collector-shorting region 35 comprises an annular portion 35a formed at a region opposite to the annular portion 24a of the gate bus line 24, a stem portion 35b so formed as to face the stem portion 24b, and a rectangular portion 35c formed at a region opposite to the gate electrode pad 25. As illustrated in FIG. 5, the first collector-shorting region 35 is formed in such a manner as to penetrate the collector region 12 and the buffer region 16, and protrude from the buffer region 16. That is, unlike the collector-shorting region 15 in the first embodiment, the first collector-shorting region 35 is formed in such a manner as to extend from the collector electrode 21 to the N-type base region 11. Consequently, the thickness of the first collector-shorting region 35 is thicker than the sum of the thicknesses of the collector region 12 and the buffer region 16, and is, for example, 25μm.

The second collector-shorting region 36 comprises an N-type semiconductor region in which N-type impurities like phosphorus are diffused. As illustrated in FIGS. 4 and 5, the second collector-shorting region 36 is formed under the buffer region 16 in such a manner as to face the gate electrode 22, and formed in the collector region 12 in such a manner as to penetrate the collector region 12. Unlike the first collector-shorting region 35, the second collector-shorting region 36 is so formed as to have the same thickness as that of the collector region 12. The second collector-shorting region 36 is formed in such a manner as to have a thickness of, for example, 4 to 6 μm or so. In comparison with the first collector-shorting region 35, the second collector-shorting region 36 has a smaller area. The impurity concentration of the second collector-shorting region 36 is higher than that of the N-type base region 11. Specifically, the impurity concentration of the second collector-shorting region 36 is, for example, 1×10^{19 cm}⁻or so.

It is preferable that the area of the first collector-shorting region should be greater than or equal to three times the area of the second collector-shorting region 36, and further preferably, greater than or equal to five times. Such a size of the area makes it possible to suppress the forward voltage property of the semiconductor device 30 from being degraded.

In the semiconductor device 30 structured in this manner, the first collector-shorting region 35 constitutes a diode together with the N-type base region 11 and the P-type semiconductor region 17 both formed upward the first collector-shorting region 35. Therefore, when reverse bias is applied to a PN junction constituted at a boundary surface between the P-type semiconductor region 17 and the N-type base region 11, a first depletion layer spreads from this PN junction boundary surface. A second depletion layer spreads from the PN junction of a boundary surface between the P-type base region 13 and the N-type base region 11.

The first collector-shorting region 35 is formed in such a manner as to extend to the N-type base region 11. Thus, the first depletion layer reaches the first collector-shorting region 35 faster than the second depletion layer reaches the second collector-shorting region 36. Accordingly, it is possible to prevent the diode from causing avalanche breakdown, which leads to latch up of the semiconductor device 10 and the breakage thereof.

When the cell region is so formed as to be relatively wide in the semiconductor substrate, even if the gate bus line 24 is constituted by the annular portion 24a and the stem portions 24b, it may be difficult to efficiently discharge carriers generated at the center of the cell region by only the first collector-shorting region 35 so formed as to correspond to the gate bus line 24. To efficiently discharge the carriers generated at the center of the cell region, a method of widely forming a collector-shorting region like conventional semiconductor devices can be expected, but this reduces the area of a collector region, so that the forward voltage property of a semiconductor device is degraded.

In the semiconductor device 30 of the embodiment, the first collector-shorting region 35 is formed in a region opposite to the gate bus line 24 and the gate electrode pad 25, and the second collector-shorting region 36 is formed in a region opposite to the gate electrode 22. Accordingly, carriers around the cell region are discharged from the first collector-shorting region 35, and carriers at the central region of the cell region are discharged from the second collector-shorting region 36.

Thus, unlike a case of the conventional technique where a collector-shorting region is formed in a cell region only, reduction of the area of a collector-shorting region (second collector-shorting region 36) in the cell region becomes possible. As a result, the area of the collector region 12 in the cell region is sufficiently secured. Consequently, the semiconductor device 30 has a good off speed (switching speed), and a good forward voltage property.

The present invention is not limited to the foregoing embodiments, and can be modified and applied in various forms.

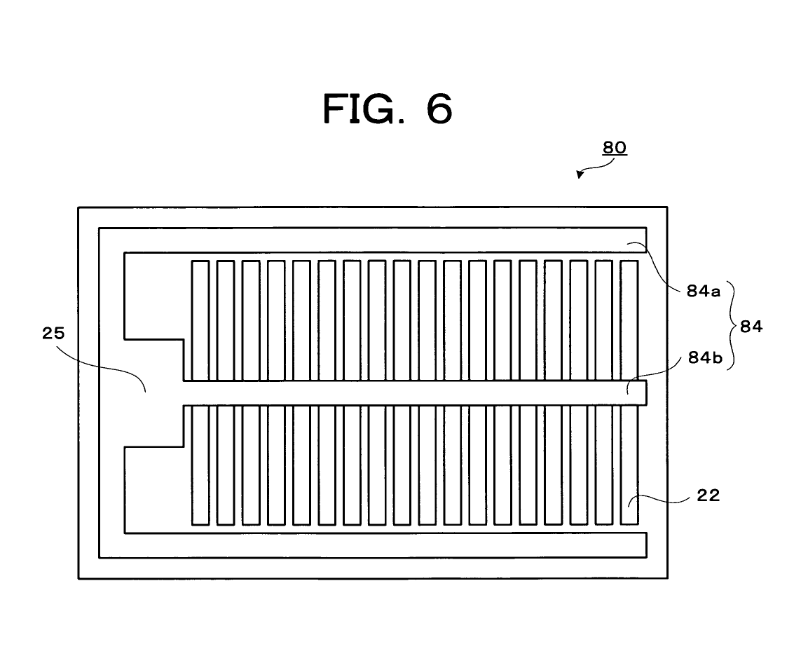

In the foregoing embodiments, the gate bus line 24 has the annular portion 24a and the stem portions 24b, and the annular portion 24a is formed in an approximately rectangular closed-loop shape. However, like a semiconductor device illustrated in FIG. 6, the gate bus line 84 may comprise an annular portion 84a with one edge opened, and a stem portion 84b extending from the gate electrode pad 25. In this case, the gate electrode 22 is disposed in such a way that the portions thereof extend from the stem portion 84b toward the annular portion 84a side by side.

The gate bus line 24 may be constituted by only the annular portion 24a. In this case, to efficiently absorb carriers generated at the center of the cell region, it is preferable that a collector-shorting region should be formed in a region opposite to the gate electrode 22 like the second embodiment.

In the foregoing embodiments, the invention has been explained with the case where the collector-shorting region is formed in a region opposite to the gate bus line 24 and the gate electrode pad 25 taken as an example. However, the collector-shorting region may not be formed in a region opposite to the gate electrode pad 25. The collector-shorting region may not be formed in an entire region opposite to the gate bus line 24 and the gate electrode pad 25, but may be formed in some portions of the region corresponding to the gate bus line 24 and the gate electrode pad 25 at predetermined intervals. In those cases, the semiconductor device can have a good forward voltage property and a good switching speed.

In the foregoing embodiment, the P-type semiconductor region 17 is formed in the surface region of the N-type base region 11 opposite to the gate bus line 24, but may not be formed at all. Although in this case, the semiconductor device can have a good forward voltage property and a good switching speed.

In the foregoing embodiment, the buffer region 16 is formed between the N-type base region 11 and the collector region 12, but may not be formed at all. Further, the foregoing semiconductor devices may be formed in such a manner as to be reverse conducting type.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2005-293017 filed on Oct. 5, 2005 and Japanese Patent Application No. 2006-247581 filed on Sep. 13, 2006 and including specification, claims, drawings and summary. The disclosure of the above Japanese Patent Application is incorporated herein by reference in its entirety.

What is claimed is:

1. A semiconductor device comprising:
a semiconductor substrate having a first semiconductor region of a first conductive type, a second semiconductor region of a second conductive type formed in a surface region of one principal surface of said first semiconductor region, a third semiconductor region of the first conductive type formed at a surface region of said second semiconductor region, and a fourth semiconductor region of the second conductive type formed on an other principal surface of said first semiconductor region;
a gate electrode disposed on said second semiconductor region through an insulating film;
a gate bus line electrically connected to said gate electrode; and
a fifth semiconductor region of the first conductive type formed in an region in said fourth semiconductor region opposite to said gate bus line.

2. The semiconductor device according to claim 1, wherein said gate bus line has an annular portion circularly formed on a periphery portion of said semiconductor substrate, and said gate electrode is disposed inward said annular portion of said gate bus line.

3. The semiconductor device according to claim 2, wherein said gate bus line further has a stem portion electrically connected to said annular portion and disposed in such a manner as to extend toward a center of said annular portion, and
said gate electrode is electrically connected to said stem portion.

4. The semiconductor device according to claim 1, wherein said fifth semiconductor region is formed in such a manner as to protrude from said fourth semiconductor region.

5. The semiconductor device according to claim 1, wherein said gate bus line is formed on said one principal surface of said first semiconductor region through an insulating layer, and a sixth semiconductor region of the second conductive type is formed at a surface region of said first semiconductor region opposite to said gate bus line.

6. The semiconductor device according to claim 5, wherein a width between said sixth semiconductor region and said second semiconductor region spaced away from each other is almost a same as a width between adjoining portions of said second semiconductor region spaced away from each other.

7. The semiconductor device according to claim 1, further comprising a seventh semiconductor region of the first conductive type formed at a region in said fourth semiconductor region opposite to said gate electrode.

8. The semiconductor device according to claim 7, wherein said fifth semiconductor region is formed in such a manner as to protrude from said fourth semiconductor region, and said seventh semiconductor region is so formed as to have an almost same thickness as a thickness of said fourth semiconductor region.

9. The semiconductor device according to claim 7, wherein said fifth semiconductor region is formed in such a manner as to have an area greater than or equal to three times an area of said seventh semiconductor region.

10. The semiconductor device according to claim 7, wherein said fifth semiconductor region is formed in such a manner as to have an area greater than or equal to five times an area of said seventh semiconductor region.

11. The semiconductor device according to claim 7, wherein said gate bus line has an annular portion circularly formed on a periphery portion of said semiconductor substrate, and said gate electrode is disposed inward said annular portion of said gate bus line.

12. The semiconductor device according to claim 11, wherein said gate bus line further has a stem portion electrically connected to said annular portion and disposed in such a manner as to extend toward a center of said annular portion, and
said gate electrode is electrically connected to said stem portion.

13. The semiconductor device according to claim 7, wherein said gate bus line is formed on said one principal surface of said first semiconductor region through an insulating layer, and a sixth semiconductor region of the second conductive type is formed at a surface region of said first semiconductor region opposite to said gate bus line.

14. The semiconductor device according to claim 13, wherein a width between said sixth semiconductor region and said second semiconductor region spaced away with each other is almost a same as a width between adjoining portions of said second semiconductor region spaced away from each other.

15. The semiconductor device according to claim 1, further comprising a gate electrode pad formed on said semiconductor substrate, and electrically connected to said gate bus line, and wherein
said fifth semiconductor region is formed in regions in said fourth semiconductor region opposite to said gate bus line and said gate electrode pad.

16. The semiconductor device according to claim 1, further comprising an eighth semiconductor region of the first conductive type formed between said first semiconductor region and said fourth semiconductor region.
